(19) United States
(12) Patent Application Publication
(10) Pub. No.: US 2015/0097269 A1
(43) Pub. Date: Apr. 9, 2015

(54) TRANSIENT VOLTAGE SUPPRESSION DEVICE AND MANUFACTURING METHOD THEREOF

(71) Applicants: Tsung-Yi Huang, HsinChu (TW); Wu-Te Weng, HsinChu (TW)

(72) Inventors: Tsung-Yi Huang, HsinChu (TW); Wu-Te Weng, HsinChu (TW)

(73) Assignee: RICHTEK TECHNOLOGY CORPORATION, Zhubei City (TW)

(21) Appl. No.: 14/049,028

(22) Filed: Oct. 8, 2013

(51) Int. Cl. H01L 27/02; H01L 29/66; H01L 29/866; H01L 29/73

(52) U.S. Cl. CPC H01L 27/0259; H01L 29/7302; H01L 29/66234; H01L 29/866; H01L 29/66106
USPC 257/577; 438/328

(57) ABSTRACT

The present invention discloses a transient voltage suppression (TVS) device and a manufacturing method thereof. The TVS device includes: a conductive layer; a P-type semiconductor substrate, which is formed on the conductive layer; an N-type buried layer, which is formed on the semiconductor substrate; a P-type lightly doped layer, which is formed on the buried layer; a P-type cap region, which is formed on the lightly doped layer; and an N-type reverse region, which is formed on the cap region, wherein a Zener diode includes the reverse region and the cap region, and an NPN bipolar junction transistor (BJT) includes the reverse region, the cap region, the lightly doped layer and the buried layer.

### BACKGROUND OF THE INVENTION

1. Field of Invention

The present invention relates to a transient voltage suppression (TVS) device and a manufacturing method thereof; particularly, it relates to such TVS device with a reduced leakage current and a manufacturing method thereof.

2. Description of Related Art

FIG. 1A shows a schematic diagram of a typical transient voltage suppression (TVS) device 100 and a protected circuit/device 1. As shown in FIG. 1A, the TVS device 100 and the protected circuit/device 1 are connected in parallel between a pad 2 and a ground level (GND) or power supply level (Vdd). When one of the terminals which are coupled to the TVS device 100 and the protected circuit/device 1 contacts a transient voltage for example caused by static charges (indicated by a lightening symbol shown in FIG. 1A), the TVS device 100 is triggered, such that the transient voltage is suppressed by the TVS device 100 to prevent the protected circuit/device 1 from being damaged by the transient voltage.

The TVS device 100 for example includes a Zener diode as shown in FIG. 1B. The TVS device 100 includes a P-type semiconductor substrate 11, a P-type well 13, a P-type cap region 15, an N-type reverse region 17, and a conductive layer 19. In one application, the conductive layer 19 is electrically connected to aground level (GND), and the N-type reverse region 17 is electrically connected to the pad 2. When the transient voltage exceeds a breakdown voltage of the Zener diode (referred to as “Zener breakdown voltage”), an electrical breakdown (referred to as “Zener breakdown”) occurs in the TVS device 100. Referring back to FIG. 1A, when the Zener breakdown occurs, a current I flows through the TVS device 100 and the voltage drop between the pad 2 and the GND is controlled at a voltage V, such that the protected circuit/device 1 will not contact a voltage higher than the voltage V.

FIG. 3 shows the voltage-current (V-I) characteristic curves of the TVS device 100 and a TVS device 200 according to the present invention (the TVS device 200 will be described later), wherein the V-I characteristic curve of the TVS device 100 is indicated by a square-dot curve. As shown in the figure, when the transient voltage caused by the static charges exceeds the trigger voltage (about 5V, as indicated by a dashed line shown in the figure), the TVS device 100 releases the static charges by the current I. However, when the protected circuit/device 1 is in normal operation, for example when the voltage drop between the pad 2 and the GND is 3.3V, a significant amount of leakage current flows through the TVS device 100 as indicated by the dashed circle. The leakage current is induced by a band-to-band tunneling effect between energy bands in the TVS device 100. The band-to-band tunneling effect induces the leakage current flowing between the reverse region 17 and the P-type cap region 15 before the Zener breakdown occurs.

Therefore, to overcome the drawbacks in the prior art, the present invention proposes an TVS device and a manufacturing method thereof, wherein the leakage current can be reduced, and the manufacturing steps of the TVS device can be integrated in the manufacturing steps of a typical semiconductor device.

### SUMMARY OF THE INVENTION

From one perspective, the present invention provides a transient voltage suppression (TVS) device, including: a conductive layer; a P-type semiconductor substrate, which is formed on the conductive layer; an N-type buried layer, which is formed on the semiconductor substrate; a P-type lightly doped layer, which is formed on the buried layer; a P-type cap region, which is formed on the lightly doped layer; and an N-type reverse region, which is formed on the cap region; wherein a Zener diode includes the reverse region and the cap region, and an NPN bipolar junction transistor (BJT) includes the reverse region, the cap region, the lightly doped layer and the buried layer.

In one preferable embodiment, the TVS device further includes an N-type high voltage well, which is formed on the buried layer and is connected to the lightly doped layer in a lateral direction to form an energy barrier between the high voltage well and the lightly doped layer.

In one preferable embodiment, the reverse region, the cap region, and the lightly doped layer are formed in an epitaxial layer.

In one preferable embodiment, when a Zener breakdown occurs in the Zener diode, a transient current flows through the NPN BJT to suppress a transient voltage.

From another perspective, the present invention provides a manufacturing method of a transient voltage suppression (TVS) device including: providing a P-type semiconductor substrate, wherein the semiconductor substrate has an upper surface and a lower surface; forming an N-type initial buried layer beneath the upper surface; forming a P-type epitaxial layer on the upper surface; forming a P-type cap region in the epitaxial layer; forming an N-type reverse region on the cap region in the epitaxial layer; forming a P-type lightly doped layer between the initial buried layer and the cap region in the epitaxial layer; performing a thermal step so that the initial buried layer diffuses to become an N-type diffused buried layer; and forming a conductive layer beneath the lower surface; wherein a Zener diode includes the reverse region and the cap region, and an NPN bipolar junction transistor (BJT) includes the reverse region, the cap region, the lightly doped layer and the buried layer.

In one preferable embodiment, a first doping concentration of P-type impurities in the cap region is higher than a second doping concentration of P-type impurities in the lightly doped layer.

In one preferable embodiment, the P-type lightly doped layer is formed by a part of the epitaxial layer.

The objectives, technical details, features, and effects of the present invention will be better understood with regard to the detailed description of the embodiments below.

### BRIEF DESCRIPTION OF THE DRAWINGS

FIG. 1A shows a schematic diagram of a prior art transient voltage suppression (TVS) device 100 and a protected circuit/device 1.

FIG. 1B shows a schematic diagram of the prior art TVS device 100 from cross-section view.

FIGS. 2A-2F show a first embodiment of the present invention.

FIG. 3 shows voltage-current characteristic curves of the TVS devices according to prior art and the present invention.

FIG. 4 shows a second embodiment of the present invention.

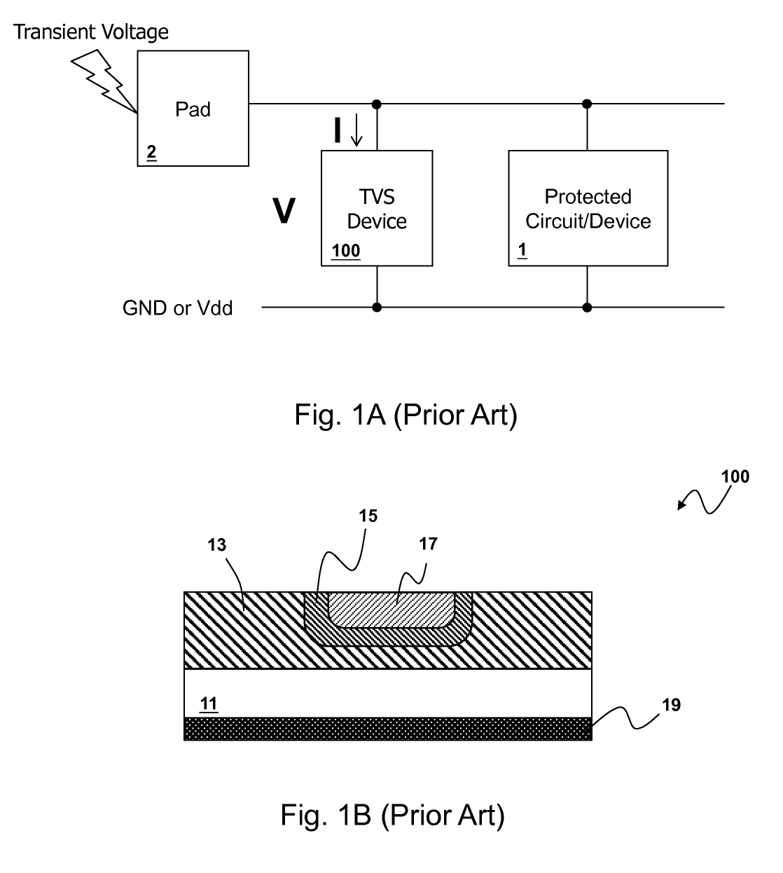

### DESCRIPTION OF THE PREFERRED EMBODIMENTS

The drawings as referred to throughout the description of the present invention are for illustration only, to show the interrelations between the regions and the steps, but not drawn according to actual scale.

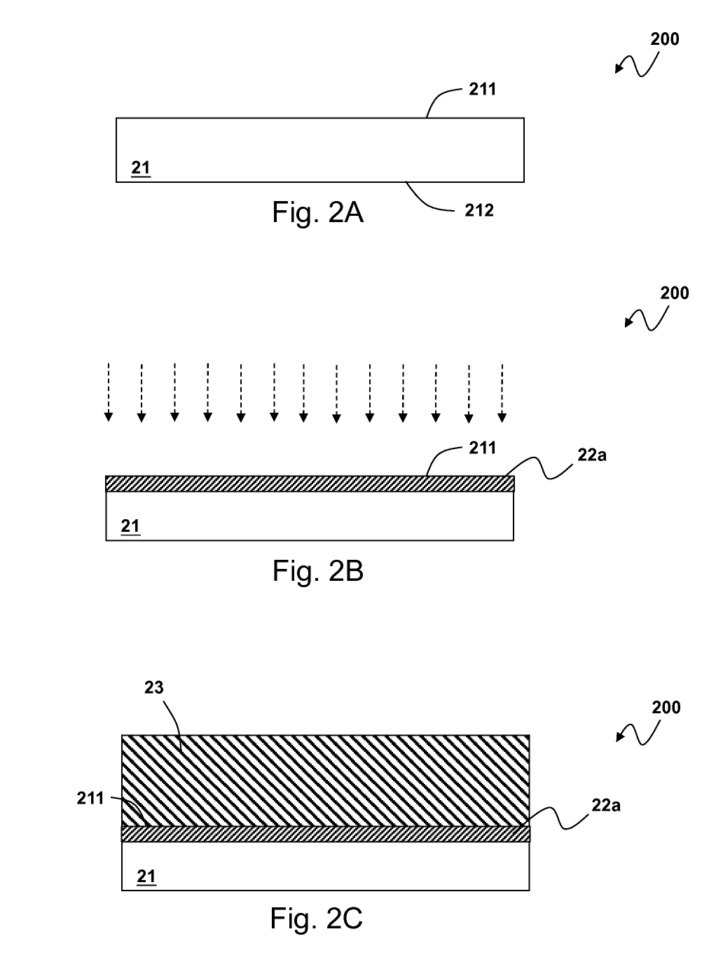

Please refer to FIGS. 2A-2F for a first embodiment according to the present invention, wherein FIGS. 2A-2F are cross-section diagrams showing a manufacturing method of a transient voltage suppression (TVS) device 200. As shown in FIG. 2A, first, a P-type semiconductor substrate 21 is provided. The semiconductor substrate 21 has an upper surface 211 and a lower surface 212, and the semiconductor substrate 21 is for example but not limited to a P-type silicon substrate, or any other kind of semiconductor substrate. Next, referring to FIG. 2B, an initial buried layer 22a is formed beneath the upper surface 211 in the semiconductor substrate 21. The initial buried layer 22a maybe formed by an ion implantation step which implants N-type impurities in the semiconductor substrate 21 in the form of accelerated ions as indicated by the dashed arrow lines, to form the N-type initial buried 22a in the P-type semiconductor substrate 21 beneath the upper surface 211.

Next, as shown in FIGS. 2C, a P-type epitaxial layer 23 is formed on the upper surface 211 by for example but not limited to an epitaxial growth step. The epitaxial layer 23 for example includes the same material as the semiconductor substrate 21, which is for example but not limited to silicon.

Next, as shown in FIG. 2D, a P-type cap region 25 is formed in the epitaxial layer 23. Next, an N-type reverse region 27 is formed on the cap region 25 in the epitaxial 23. According to the present invention, a P-type lightly doped layer is formed between the initial buried layer 22a and the cap region 25; in this embodiment, the lightly doped layer for example is the epitaxial layer 23 itself (i.e., formed by a part of the epitaxial layer 23). In another embodiment, a part of the epitaxial layer 23 between the initial buried layer 22a and the cap region 25 can be doped by more P-type impurities or counter-doped by N-type impurities to adjust the concentration of the P-type lightly doped layer.

Next, as shown in FIG. 2E, a thermal step is performed whereby the initial buried layer 22a becomes an N-type diffused buried layer 22. The N-type impurities in the initial buried layer 22a are diffused from the semiconductor substrate 21 across the upper surface 211 to the epitaxial layer 23 by the thermal step. Next, as shown in FIG. 2F, a conductive layer 29 is formed beneath the lower surface 212 of the semiconductor substrate 21. The conductive layer 29 is an electrical contact of the semiconductor substrate 21, which for example can be coupled to a ground level (GND) or power supply level (Vdd).

The TVS device 200 includes a Zener diode and an NPN BJT as indicated by the dashed symbols of the BJT and the Zener diode shown in the figure. The Zener diode includes the reverse region 27 and the cap region 25. The NPN BJT includes the reverse region 27, the cap region 25, the epitaxial layer 23 (i.e., the lightly doped layer), and the buried layer 22.

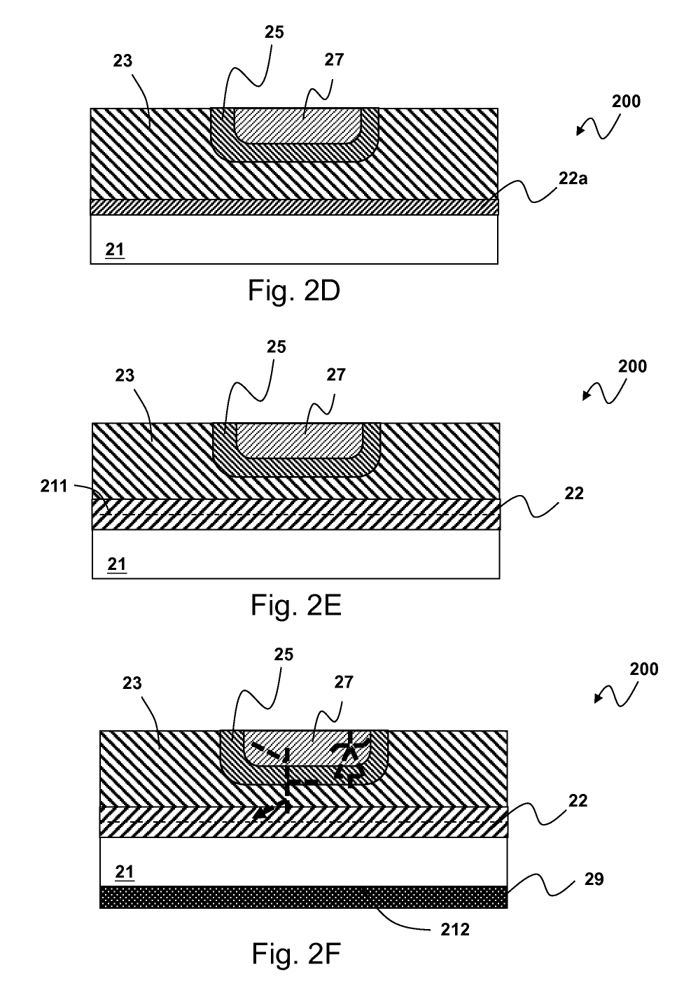

When the TVS device 200 contacts a transient voltage which exceeds a Zener breakdown voltage of the Zener diode in the TVS device 200, a Zener breakdown occurs and the NPN BJT turns ON, such that a transient current flows through the NPN BJT to suppress the transient voltage. The TVS device according to the present invention may be embodied in a P-type silicon substrate, which is a typical semiconductor substrate for manufacturing semiconductor devices, and it is not required to use an N-type semiconductor substrate which is more costly. FIG. 3 shows the voltage-current (V-I) characteristic curves of the prior art TVS device 100 and the TVS device 200 according to the present invention, wherein the V-I characteristic curve of the TVS device 200 is indicated by a star-dot curve shown in the figure. As FIG. 3 shows, when the transient voltage caused by the static charges exceeds the trigger voltage (about 5V), the TVS device 200 releases static charges by the current I. On the other hand, when the protected circuit/device 1 is in normal operation, for example when the voltage drop between the pad 2 and the GND is 3.3V, the leakage current flowing through the TVS device 200 is lower than the leakage current of the TVS device 100 as indicated by a dashed arrow, because the leakage current in the BJT of the TVS device 200 is relatively lower. Note that a doping concentration of the P-type impurities in the cap region 25 is preferably higher than a doping concentration of the P-type impurities in the lightly doped layer 23.

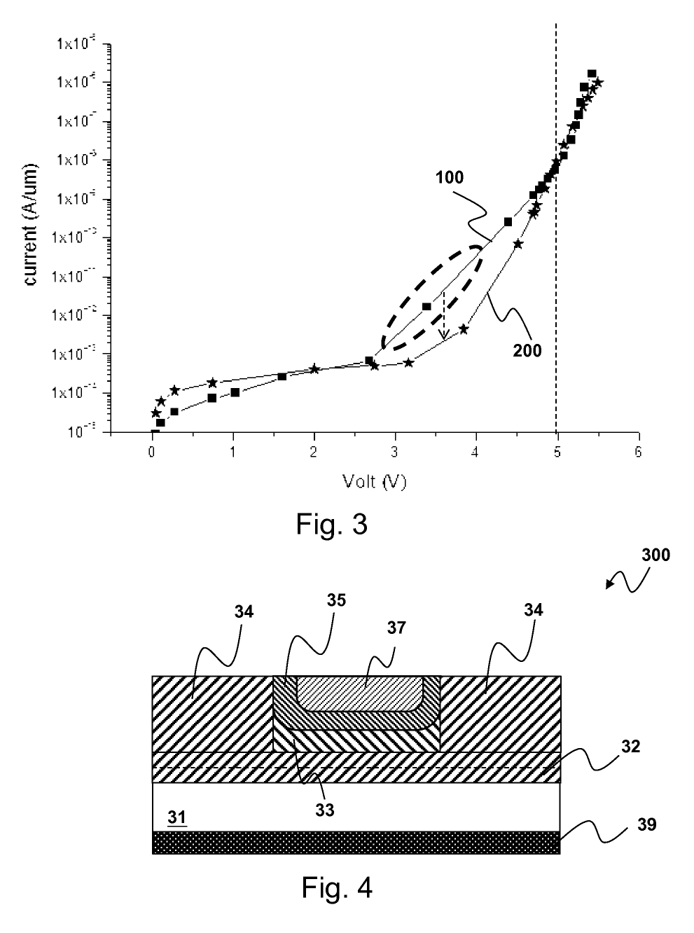

FIG. 4 shows a second embodiment of the present invention. FIG. 4 shows a cross-section view of a TVS device 300 according to the present invention. As shown in FIG. 4, the TVS device 300 includes: a semiconductor substrate 31, a buried layer 32, a lightly doped layer 33, a high voltage well 34, a cap region 35, a reverse region 37, and a conductive layer 39. The semiconductor substrate 31 has a P-type conductivity and is formed on the conductive layer 39. The buried layer 32 with a N-type conductivity is formed on the semiconductor substrate 31. The lightly doped layer 33 with the P-type conductivity is formed on the buried layer 32. The cap region 35 with the P-type conductivity is formed on the lightly doped layer 33. The reverse region 37 with the N-type conductivity is formed on the cap region 35. A Zener diode includes the reverse region 37 and the cap region 35, and an NPN BJT includes the reverse region 37, the cap region 35, the lightly doped layer 33 and the buried layer 32. This embodiment is different form the first embodiment in that, the high voltage well 34 with the N-type conductivity is formed on the buried layer 32, and is connected to the lightly doped layer 33 in a lateral direction in the cross-section view, such that an energy barrier is formed between the high voltage well 34 and the lightly doped layer 33 to further reduce the leakage current of the TVS device 300.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other steps or structures which do not affect the primary characteristic of the device, such as an isolation structure, etc., can be added. In view of the foregoing, the spirit of the present invention should cover all such and other modifications and variations, which should be interpreted to fall within the scope of the following claims and their equivalents. An embodiment or a claim of the present invention does not need to achieve all the objectives or advantages of the present invention. The title and abstract are provided for assisting searches but not for limiting the scope of the present invention.

1. A transient voltage suppression (TVS) device, comprising:
a conductive layer;
a P-type semiconductor substrate, which is formed on the conductive layer;
an N-type buried layer, which is formed on the semiconductor substrate;
a P-type lightly doped layer, which is formed on the buried layer;
a P-type cap region, which is formed on the lightly doped layer; and
an N-type reverse region, which is formed on the cap region;
wherein a Zener diode includes the reverse region and the cap region, and an NPN bipolar junction transistor (BJT) includes the reverse region, the cap region, the lightly doped layer and the buried layer.

2. The TVS device of claim 1 further comprising an N-type high voltage well, which is formed on the buried layer and is connected to the lightly doped layer in a lateral direction to form an energy barrier between the high voltage well and the lightly doped layer.

3. The TVS device of claim 1, wherein the reverse region, the cap region, and the lightly doped layer are formed in an epitaxial layer.

4. The TVS device of claim 1, wherein when a Zener breakdown occurs in the Zener diode, a transient current flows through the NPN BJT to suppress a transient voltage.

5. The TVS device of claim 1, wherein a first doping concentration of P-type impurities in the cap region is higher than a second doping concentration of P-type impurities in the lightly doped layer.

6. A manufacturing method of a transient voltage suppression (TVS) device, comprising:
providing a P-type semiconductor substrate, wherein the semiconductor substrate has an upper surface and a lower surface;
forming an N-type initial buried layer beneath the upper surface;
forming a P-type epitaxial layer on the upper surface;
forming a P-type cap region in the epitaxial layer;
forming an N-type reverse region on the cap region in the epitaxial layer;
forming a P-type lightly doped layer between the initial buried layer and the cap region in the epitaxial layer;
performing a thermal step so that the initial buried layer diffuses to become an N-type diffused buried layer; and
forming a conductive layer beneath the lower surface;
wherein a Zener diode includes the reverse region and the cap region, and an NPN bipolar junction transistor (BJT) includes the reverse region, the cap region, the lightly doped layer and the buried layer.

7. The manufacturing method of claim 6 further comprising forming an N-type high voltage well on the buried layer, the N-type high voltage well being connected to the lightly doped layer in a lateral direction to form an energy barrier between the high voltage well and the lightly doped layer.

8. The manufacturing method of claim 6, wherein when a Zener breakdown occurs in the Zener diode, a transient current flows through the NPN BJT to suppress a transient voltage.

9. The manufacturing method of claim 6, wherein a first doping concentration of P-type impurities in the cap region is higher than a second doping concentration of P-type impurities in the lightly doped layer.

10. The manufacturing method of claim 6, wherein the P-type lightly doped layer is formed by a part of the epitaxial layer.
